(19) United States
(12) Patent Application Publication
(10) Pub. No.: US 2005/0044302 A1
(43) Pub. Date: Feb. 24, 2005

(54) Non-standard dual in-line memory modules with more than two ranks of memory per module and multiple serial-presence-detect devices to simulate multiple modules

(76) Inventors: Robert S. Pauley, Mission Viejo, CA (US); Jayesh R. Bhakta, Cerritos, CA (US); William M. Gervasi, Ladera Ranch, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/913,700

(22) Filed: Aug. 6, 2004

Related U.S. Application Data
(60) Provisional application No. 60/492,886, filed on Aug. 6, 2003.
(60) Provisional application No. 60/547,816, filed on Feb. 26, 2004.

(51) Int. Cl. G11C 5/00

(52) U.S. Cl. 711/1

(57) ABSTRACT

A memory module includes a printed circuit board and a plurality of memory devices arranged in a plurality of ranks on the printed circuit board. The plurality of ranks includes a first subset having at least one rank and a second subset having at least one rank. The memory module further includes a first serial-presence-detect (SPD) device on the printed circuit board and a second SPD device on the printed circuit board. The first SPD device includes data that characterizes the first subset. The second SPD device includes data that characterizes the second subset.

### REFERENCE TO RELATED APPLICATION

This application claims the benefit of priority under 35 U.S.C. § 119(e) of U.S. Provisional Application No. 60/492,886, filed Aug. 6, 2003, the entirety of which is incorporated herein by reference, and U.S. Provisional Application No. 60/547,816, filed Feb. 26, 2004, the entirety of which is incorporated herein by reference.

### BACKGROUND OF THE INVENTION

1. Field of the Invention

This invention relates generally to configurations of Dual In-Line Memory Modules (DIMMs) that contain more than two ranks of memory per DIMM.

2. Description of the Related Art

A typical computer system includes a computer memory subsystem comprising a memory controller and a plurality of memory connectors or slots. Each memory slot is configured to receive a memory module to provide memory capacity to the computer system. The memory controller typically comprises at least one integrated circuit chip which communicates with the installed memory modules (e.g., executing read and write commands, receiving data from and sending data to the installed memory modules). Each memory slot has a unique memory slot address and each memory slot electrically connects the installed memory module to the memory controller, thereby allowing the computer system to selectively access the memory modules.

Each memory module comprises a plurality of memory devices (e.g., dynamic random access memory or DRAM devices). For example, double-data-rate (DDR) dual in-line memory modules (DIMMs) have two ranks (or rows or physical banks) of DRAM devices. Each rank is a collection of DRAM devices which share a chip-select (CS#) signal from the memory controller to make up a module-width word. For example, 16 DRAM devices, each with a 4-bit-wide interface, can be used to make a 64-bit-wide module interface.

While DDR DIMMs have two ranks of memory devices, they have provisions for four rank-select inputs, identified as S0#-S3#. As schematically illustrated by FIG. 1A, standard two-rank memory modules use only two rank-select inputs (S0#, S1#) for each memory slot, leaving the remaining two rank-select inputs (S2#, S3#) unused. The memory controller routes two chip-select signals to each memory slot to control the two ranks of memory in each memory module, as standardized by the Joint Electronic Device Engineering Council (JEDEC).

For example, as shown schematically by FIG. 1A, a typical computer system with four slots routes chip-select signals CS0# and CS1# to the two rank-select inputs of slot 0, CS2# and CS3# to the two rank-select inputs of slot 1, CS4# and CS5# to the two rank-select inputs of slot 2, and CS6# and CS7# to the two rank-select inputs of slot 3. In addition, the memory controller provides eight clock-enable signals (CKE0-CKE7), two of which are routed to each memory slot, as schematically illustrated by FIG. 1A. In addition, the computer system typically includes an address bus (not shown) and a data bus (not shown) to clock address and data information into and out of the memory module.

Other computer systems have other numbers of memory slots. For example, memory controllers used in a server class of computer systems utilize a memory controller hub (MCH) with up to eight memory slots (e.g., two memory channels of four memory slots each), which can support up to eight memory modules with two ranks per module. Such memory controllers can provide up to sixteen chip-select signals connected to the eight memory slots.

DDR dual in-line memory modules also comprise a serial-presence-detect (SPD) device which contains information about the memory module (e.g., memory density, configuration, timing, and other performance parameters). Typically, the SPD device comprises an electrically-erasable-programmable-read-only memory (EEPROM). The SPD device provides this information to the basic input/output system (BIOS) of the computer system via an I²C bus which has a serial clock (SCL) line and a serial data (SDA) line. The SPD device has a set of serial address (SA) inputs which receive serial bus address signals from the memory slot corresponding to the unique memory slot address of the memory slot in which the memory module is installed. FIG. 1B schematically illustrates four memory modules in four corresponding memory slots, each memory slot having a unique address. Each memory module also has an SPD device which receives the serial bus address signals from the memory slot. These address signals provide the SPD device with a unique polling address corresponding to the memory slot address. The SA inputs are binary-coded (i.e., either logic-high or logic-low), so three SA inputs can uniquely address up to eight SPD devices. The SPD device then responds to the unique polling address when polled by the BIOS via the I²C bus. Upon application of power to the computer system, the BIOS performs various functions, including polling the SPD devices of the installed memory modules and receiving data from the SPD devices regarding the available memory capacity of the installed memory modules.

### SUMMARY OF THE INVENTION

In certain embodiments, a memory module comprises a printed circuit board, and a plurality of memory devices arranged in a plurality of ranks on the printed circuit board. The plurality of ranks comprises a first subset having at least one rank and a second subset having at least one rank. The memory module further comprises a first serial-presence-detect (SPD) device on the printed circuit board, where the first SPD device comprises data that characterizes the first subset. The memory module further comprises a second SPD device on the printed circuit board, where the second SPD device comprises data that characterizes the second subset.

In certain embodiments, a memory module comprises a first rank of memory devices, a second rank of memory devices, a third rank of memory devices, and a fourth rank of memory devices. The memory module further comprises a first serial-presence-detect (SPD) device and a second SPD device. The first SPD device comprises data that characterizes the first rank of memory devices and the second rank of memory devices. The second SPD device comprises data that characterizes the third rank of memory devices and the fourth rank of memory devices. The memory module further comprises a plurality of address inputs configured to provide the first SPD device with a first polling address. The memory module further comprises a circuit electrically coupled to the plurality of address inputs and configured to provide the second SPD device with a second polling address different from the first polling address.

In certain embodiments, a method of addressing memory in a computer system comprises providing a four-rank memory module comprising a printed circuit board. The four-rank memory module further comprises a first pair of memory ranks on the printed circuit board and a second pair of memory ranks on the printed circuit board. The four-rank memory module further comprises a first serial-presence-detect (SPD) device on the printed circuit board and a second SPD device on the printed circuit board. The first SPD device comprises data that characterizes the first pair of memory ranks, and the second SPD device comprises data that characterizes the second pair of memory ranks. The method further comprises electrically connecting the four-rank memory module to a memory controller. The method further comprises applying a first polling address to the first SPD device based on a physical location of the four-rank memory module in the computer system. The method further comprises generating a second polling address different from the first polling address, and applying the second polling address to the second SPD device.

In certain embodiments, a computer memory subsystem comprises a memory controller and a four-rank memory module with a first group of two memory ranks and a second group of two memory ranks. The four-rank memory module further comprises a first serial-presence-detect device and a second serial-presence-detect device. The first serial-presence-detect device comprises data associated with the first group of two memory ranks, and the second serial-presence-detect device comprises data associated with the second group of two memory ranks. The computer memory subsystem further comprises means for electrically connecting the four-rank memory module to the memory controller. The computer memory subsystem further comprises means for configuring the first serial-presence-detect device with a first address. The computer memory subsystem further comprises means for generating a second address for the second serial-presence-detect device from the first address. The computer memory subsystem further comprises means for configuring the second serial-presence-detect device with the second address, where the first and second addresses are different.

In certain embodiments, a computer comprises a four-rank memory module that includes a first set of two memory ranks and a second set of two memory ranks. The computer further comprises at least one memory slot electrically coupled to the four-rank memory module. The computer further comprises a memory controller electrically coupled to the memory slot to access the four-rank memory module as two independent two-rank memory modules.

In certain embodiments, a computer system comprises a memory controller and a printed circuit board. The computer system further comprises a plurality of memory devices arranged in a plurality of ranks on the printed circuit board and electrically coupled to the memory controller. The plurality of ranks comprises a first subset having at least one rank and a second subset having at least one rank. The memory controller accesses the first subset as a first virtual memory module and accesses the second subset as a second virtual memory module.

For purposes of summarizing the invention, certain aspects, advantages and novel features have been described herein. It is to be understood that not necessarily all such advantages may be achieved in accordance with any particular embodiment. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

A general architecture that implements the various features of various embodiments are described with reference to the drawings. The drawings and the associated descriptions are provided to illustrate embodiments of the invention and not to limit the scope of the invention. Throughout the drawings, reference numbers are re-used to indicate correspondence between referenced elements.

FIG. 1A schematically illustrates a computer system with four memory slots, each slot configured to receive a two-rank memory module.

FIG. 1B schematically illustrates a computer system with four memory modules, each memory module having an SPD device.

FIGS. 2A and 2B schematically illustrate two embodiments of a memory module comprising a plurality of ranks and at least two SPD devices in accordance with embodiments described herein.

FIGS. 3A-3E schematically illustrate exemplary configurations of two SPD devices in accordance with embodiments described herein.

FIG. 4 schematically illustrates the tradeoff between bandwidth and memory density of a computer system.

FIG. 5A schematically illustrates an exemplary computer system with two 4-rank memory modules in memory slots 0 and 1 and utilizing eight clock-enable signals in accordance with embodiments described herein.

FIG. 5B schematically illustrates an exemplary computer system with two 4-rank memory modules in memory slots 0 and 1 and utilizing four clock-enable signals in accordance with embodiments described herein.

FIG. 6A schematically illustrates an exemplary computer system with two 4-rank memory modules in memory slots 0 and 2 and utilizing eight clock-enable signals in accordance with embodiments described herein.

FIG. 6B schematically illustrates an exemplary computer system with two 4-rank memory modules in memory slots 0 and 2 and utilizing four clock-enable signals in accordance with embodiments described herein.

FIG. 7 schematically illustrates an exemplary computer system with a hybrid configuration utilizing two 2-rank memory modules and two 4-rank memory modules.

### DETAILED DESCRIPTION OF THE PREFERRED EMBODIMENT

To increase computer system performance, it is often desirable to increase the memory capacity, since adding total memory capacity can be the single largest factor to increasing system performance. However, as the memory frequencies increases, the number of available memory slots decreases due to complexities involved with running electrical signals over the memory channel among different memory slots. Such limitations can force system designers to choose between low-frequency, high-capacity systems, or high-frequency, low-capacity systems. In addition, supplying additional memory slots utilizes a larger portion of the system (e.g., more space on the motherboard), thereby limiting functionality and raising costs.

One method for increasing the memory capacity of the computer system without adding system design complexity is to replace a memory module comprising lower density memory chips with a memory module comprising higher density memory chips. For example, an exemplary computer system utilizes a memory module that has a plurality of 256-Mb dynamic-random-access memory (DRAM) chips configured to provide 1-GB of memory. To increase the memory capacity of the computer system, this 1-GB memory module can be replaced with a 2-GB memory module that has a plurality of 516-Mb DRAMs configured to provide 2-GB of memory with the same form factor and electrical considerations as the 1-GB memory module. However, this method of increasing the memory capacity is not cost-effective until the price per memory bit crossover occurs between the older, more mature memory device, such as the 256-Mb DRAM, and the newer memory device, such as the 512-Mb DRAM.

Another method for increasing the memory capacity of the computer system is to provide memory modules with additional memory devices (e.g., with more than the two ranks of memory devices of standard memory modules). Each memory module has a serial-presence-detect (SPD) device that stores configuration information regarding the memory module. Under JEDEC standards, the SPD device of a memory module defines a field, Byte 5, as describing the number of ranks of memory devices on the memory module. Total module capacity is calculated by multiplying the content of SPD Byte 31 (Module Bank Density) by the content of SPD Byte 5 (Number of Ranks). As shown by Table 1, SPD Byte 5 can be set to indicate whether the memory module comprises 1, 2, or 4 ranks of memory modules.

TABLE 1
SPD Byte 5: Number of Ranks

| Ranks | Bit 7 | Bit 6 | Bit 5 | Bit 4 | Bit 3 | Bit 2 | Bit 1 | Bit 0 | Hex |
|---|---|---|---|---|---|---|---|---|---|
| Un- | 0 | 0 | 0 | 0 | 0 | 0 | 0 | 0 | 00 |
| defined | | | | | | | | | |
| 1 | 0 | 0 | 0 | 0 | 0 | 0 | 0 | 1 | 01 |
| 2 | 0 | 0 | 0 | 0 | 0 | 0 | 1 | 0 | 02 |
| 3 | 0 | 0 | 0 | 0 | 0 | 0 | 1 | 1 | 03 |
| 4 | 0 | 0 | 0 | 0 | 0 | 1 | 0 | 0 | 04 |
| . | . | . | . | . | . | . | . | . | . |
| . | . | . | . | . | . | . | . | . | . |
| . | . | . | . | . | . | . | . | . | . |

Since standard computer systems utilize only two chip-select signals per memory slot, some BIOS code will not correctly decode SPD Byte 5 as indicating more than two ranks. To accommodate changing the SPD Byte 5 in this way, minor changes to the BIOS code are made so that the correct chip-select signals and clock-enable signals are activated by the computer system. Typically, such changes to the BIOS code involve fewer than 20 lines of code, and the code is specific to the central processing unit and the memory controller of the computer system. A general algorithm describing the BIOS code change is as follows:

```
// Determine mapping of chip-select and clock-enable signals to memory
slots
switch (SPD[5])
{
    case 1: map_cs_cke(ONE_RANK); break;
    case 2: map_cs_cke(TWO_RANKS); break;
    case 4: map_cs_cke(FOUR_RANKS); break; //New code
}
// Continue processing the SPD
```

Certain computer systems do not have all of their memory slots populated by memory modules as a system design choice, leaving some of the chip-select signals unused. In such computer systems, the memory capacity can be increased by using the previously-unused chip-select signals for the unpopulated memory slots to control additional ranks on non-standard memory modules. In certain other computer systems, the memory controller provides more than two chip-select signals per memory slot (e.g., four chip-select signals per memory slot). When used with standard two-rank memory modules, these additional chip-select signals are unused. When used with non-standard memory modules with more than two ranks per memory module, the previously-unused chip-select signals are used to control the additional ranks of memory in each memory module. However, to use previously-unused chip-select signals to control additional ranks also involves modifications of the BIOS as described above to recognize the additional ranks of memory per memory module. This modification of the BIOS is difficult for users that do not write their own BIOS or that cannot change the BIOS for legacy reasons.

Memory Module with Two SPD Devices

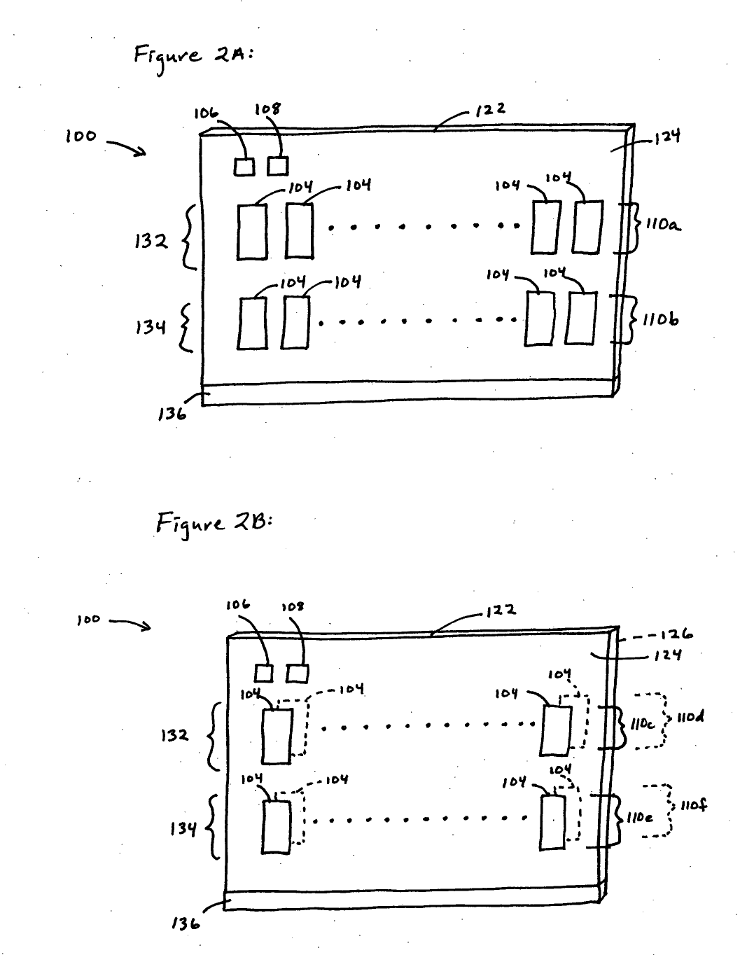

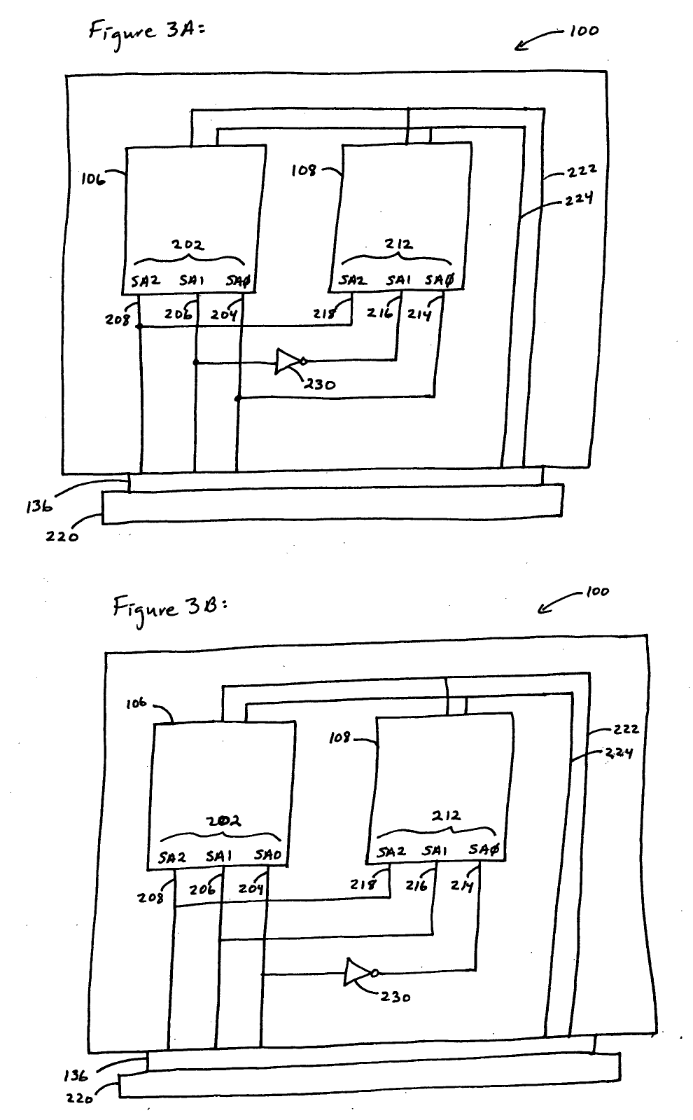

FIGS. 2A and 2B schematically illustrate two exemplary embodiments of a memory module 100 in accordance with embodiments described herein. Each of the memory modules 100 schematically illustrated by FIGS. 2A and 2B comprises a printed circuit board (PCB) 122 and a plurality of memory devices 104 arranged in a plurality of ranks 110 on the PCB 122. The plurality of ranks 110 comprises a first subset 132 and a second subset 134. The memory module 100 further comprises a first serial-presence-detect (SPD) device 106 mounted on the PCB 122, and a second SPD device 108 mounted on the PCB 122. The first SPD device 106 comprises data that characterizes the first subset 132 and the second SPD device 108 comprises data that characterizes the second subset 134. The memory module 100 of certain embodiments further comprises an edge connector 136 which is connectable to a memory slot of the computer system (not shown) and which provides electrical connection between the memory devices 104 of the memory module 100 and the computer system. In the memory module 100 schematically illustrated by FIG. 2A, the first subset 132 comprises a first rank 110a and the second subset 134 comprises a second rank 110b. Similarly, the memory module 100 schematically illustrated by FIG. 2B comprises four ranks, with the first subset 132 having two ranks 110c, 110d, and the second subset 134 having two ranks 110e, 110f.

In certain embodiments, the plurality of ranks 110 include, but are not limited to, greater than two ranks, and greater than four ranks. In certain embodiments, the first subset 132 and the second subset 134 each have at least one rank (e.g., one, two, three, four, or more ranks). Each of the first subset 132 and the second subset 134 of the embodiment schematically illustrated by FIG. 2A has one rank. Each of the first subset 132 and the second subset 134 of the embodiment schematically illustrated by FIG. 2B has two ranks. In certain embodiments, each rank 110 of the plurality of ranks 110 comprises a plurality of memory devices 104 which share a chip-select signal.

In the embodiment schematically illustrated by FIG. 2A, the first subset 132 and the second subset 134 are mounted on the same side 124 of the PCB 122. In the embodiment schematically illustrated by FIG. 2B, the first subset 132 and the second subset 134 each comprises at least one rank 110 on a first side 124 of the PCB 122 and at least one rank 110 on a second side 126 of the PCB 122. In other embodiments, the ranks 110 of the first subset 132 are on a single side of the PCB 122 and the ranks 110 of the second subset 134 are on an opposite side of the PCB 122. In still other embodiments, at least one of the ranks 110 of the first subset 132 comprises one or more memory modules 104 on the first side 124 of the PCB 122 and one or more memory modules 104 on the second side 126 of the PCB 122. Similarly, in still other embodiments, at least one of the ranks 110 of the second subset 134 comprises one or more memory modules 104 on the first side 124 of the PCB 122 and one or more memory modules 104 on the second side 126 of the PCB 122.

Memory devices 104 compatible with embodiments described herein include, but are not limited to, random-access memory (RAM), dynamic-random-access memory (DRAM), synchronous-dynamic-random-access memory (SDRAM), double-data-rate dynamic-random-access memory (e.g., DDR, DDR2, DDR3), extended-data-out dynamic random-access memory (EDO DRAM), fast-page dynamic-random-access memory (FP DRAM), video random-access memory (VRAM), cached-dynamic-random-access memory (CDRAM), Rambus-dynamic-random-access memory (RDRAM), ferroelectric random-access memory (FRAM), flash memory, read-only memory (ROM), one-time-programmable read-only memory (OTP ROM), programmable-read-only memory (PROM), erasable-programmable-read-only memory (EPROM), and electrically-erasable-programmable-read-only memory (EEPROM). Memory modules 100 compatible with embodiments described herein include, but are not limited to in-line memory modules, dual in-line memory modules (DIMMs), small-outline dual in-line memory modules (SO DIMMs), mini dual in-line memory modules (Mini-DIMMs), and micro dual in-line memory modules (Micro-DIMMs).

SPD devices 106, 108 compatible with embodiments described herein include, but are not limited to, electrically-erasable-programmable-read-only memory (EEPROM) devices and serial EEPROM devices. Other embodiments utilize other SPD devices 106, 108 which are configured to store data that characterizes the respective subsets of the plurality of ranks 110 of the memory module 100. In certain embodiments, the first SPD device 106 and the second SPD device 108 are mounted on the same side of the PCB 122. In other embodiments, the first SPD device 106 and the second SPD device 108 are mounted on opposite sides of the PCB 122. In certain embodiments, the first SPD device 106 and the first subset 132 are mounted on the same side of the PCB 122, while in other embodiments, the first SPD device 106 and the first subset 132 are mounted on opposite sides of the PCB 122. In certain embodiments, the second SPD device 108 and the second subset 134 are mounted on the same side of the PCB 122, while in other embodiments, the second SPD device 108 and the second subset 134 are mounted on opposite sides of the PCB 122.

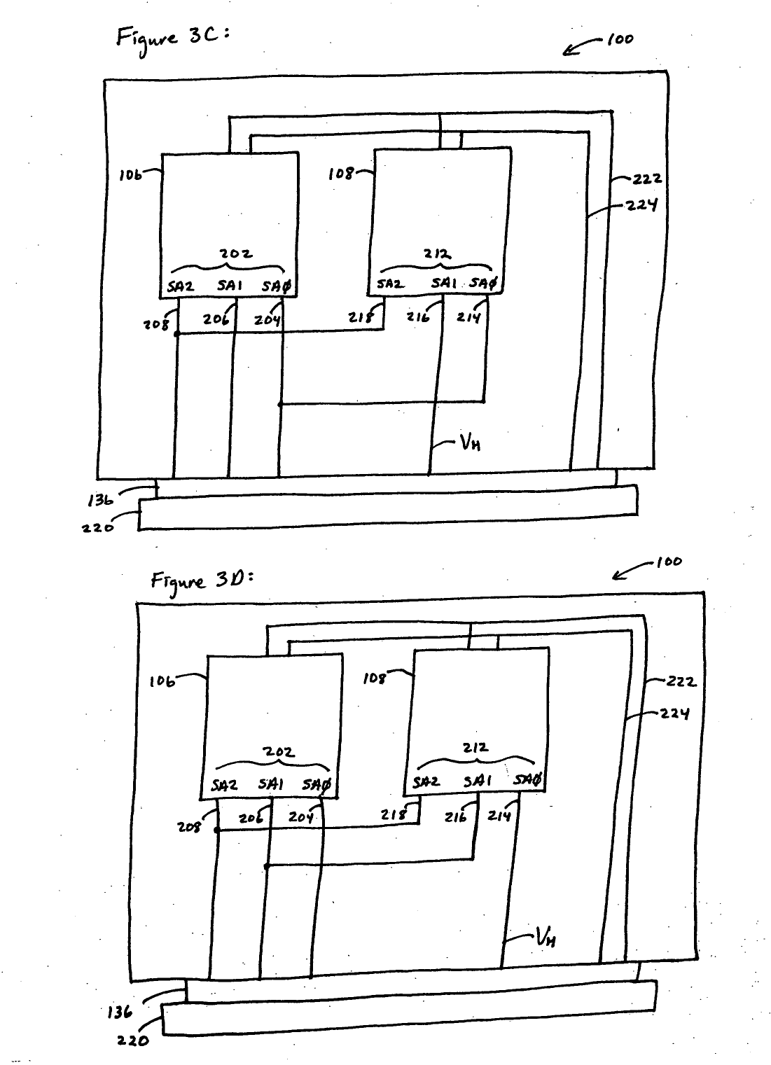

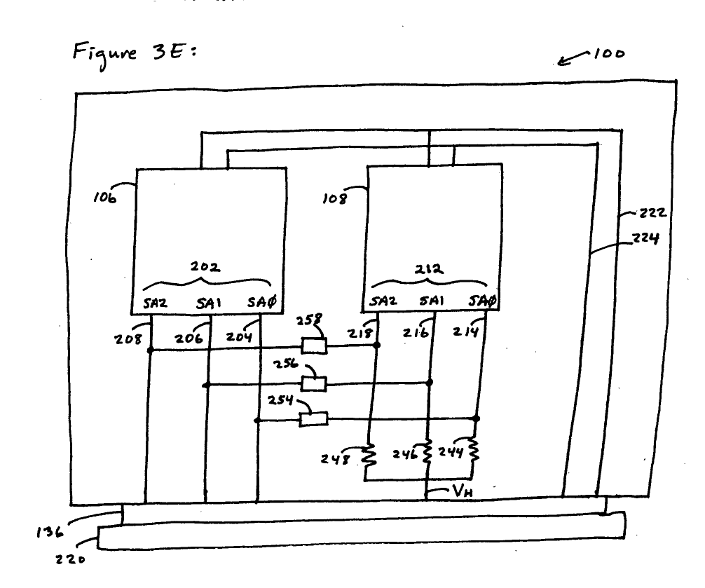

FIGS. 3A-3E schematically illustrate various exemplary configurations of a memory module 100 with a first SPD device 106 and a second SPD device 108 in accordance with embodiments described herein. The memory module 100 provides the first SPD device 106 with a first polling address and provides the second SPD device 108 with a second polling address. In certain embodiments, the second polling address is different from the first polling address. The first polling address of certain embodiments is provided to a first set 202 of address inputs (SA0, SA1, SA2) of the first SPD device 106. The first set 202 of address inputs are electrically connected to the computer system through contacts (e.g., pins or balls of a ball-grid array) to the connector 136 which is electrically coupled to the memory slot 220. The second polling address of certain embodiments is provided to a second set 212 of address inputs (SA2, SA1, SA0) of the second SPD device 108, at least some of which are electrically connected through contacts (e.g., pins or balls of a ball-grid array) to the first set 202 of address inputs. In certain embodiments, each of the SPD devices 106, 108 is electrically connected to the I²C bus of the computer system by the SCL line 222 and the SDA line 224 via the connector 136 and the memory slot 220.

In certain embodiments, the first set 202 of address inputs of the first SPD device 106 comprises a first address input 204 corresponding to a first address bit (SA0), a second address input 206 corresponding to a second address bit (SA1), and a third address input 208 corresponding to a third address bit (SA2). Similarly, in certain embodiments, the second set 212 of address inputs of the second SPD device 108 also comprises a first address input 214 corresponding to a first address bit (SA0), a second address input 216 corresponding to a second address bit (SA1), and a third address input 218 corresponding to a third address bit (SA2).

In the embodiment schematically illustrated by FIG. 3A, the first set 202 of address inputs of the first SPD device 106 are configured to receive address signals from the memory controller through the memory slot 220 and the connector 136. The first address input 204 of the first SPD device 106 is electrically coupled to the first address input 214 of the second SPD device 108. Similarly, the third address input 208 of the first SPD device 106 is electrically coupled to the third address input 218 of the second SPD device 108. The second address input 216 of the second SPD device 108 is electrically coupled to the second address input 206 of the first SPD device 106 via an inverter 230 in the embodiment schematically illustrated by FIG. 3A. An input of the inverter 230 is electrically coupled to the second address bit 206 of the first SPD device 106 and an output of the inverter 230 is electrically coupled to the second address bit 216 of the second SPD device 108

In the embodiment schematically illustrated by FIG. 3A, the first SPD device 106 and the second SPD device 108 have different polling addresses regardless of the memory slot address signals received by the memory module 100 from the memory controller. Table 2 shows the first polling address of the first SPD device 106 and the second polling address of the second SPD device 108 for various memory slots in which the memory module 100 schematically illustrated by FIG. 3A can be installed. The first polling address of the first SPD device 106 is based on the physical location of the memory module 100 in the computer system (e.g., which memory slot the memory module occupies). The second polling address of the second SPD device 108 is generated from the first polling address of the first SPD device 106. The computer system of certain embodiments has eight memory slots, while the computer system of other embodiments has less than eight memory slots (e.g., four memory slots) which can accommodate fewer memory modules.

TABLE 2

| | | First polling | Second polling |
|---|---|---|---|
| Memory slot | Memory slot | address of | address of |
| occupied by the | address | first SPD device | second SPD device |
| memory module | signals | (SA2, SA1, SA0) | (SA2, SA1, SA0) |
| 0 | (0, 0, 0) | (0, 0, 0) | (0, 1, 0) |
| 1 | (0, 0, 1) | (0, 0, 1) | (0, 1, 1) |
| 2 | (0, 1, 0) | (0, 1, 0) | (0, 0, 0) |
| 3 | (0, 1, 1) | (0, 1, 1) | (0, 0, 1) |
| 4 | (1, 0, 0) | (1, 0, 0) | (1, 1, 0) |
| 5 | (1, 0, 1) | (1, 0, 1) | (1, 1, 1) |
| 6 | (1, 1, 0) | (1, 1, 0) | (1, 0, 0) |
| 7 | (1, 1, 1) | (1, 1, 1) | (1, 0, 1) |

In certain such embodiments in which the first SPD device 106 comprises data that characterizes the first subset 132 of ranks 110 and the second SPD device 108 comprises data that characterizes the second subset 134 of ranks 110, the memory module 100 simulates two memory modules with two different addresses. Although the memory module 100 is installed in a single memory slot, the memory module 100 appears to the BIOS and other components of the computer system as two virtual or “pseudo” memory modules. Each virtual memory module appears to the computer system as being in a separate memory slot, and as comprising a respective subset of the ranks 110 of the memory module 100.

For example, a 4-rank memory module 100 comprising a first subset 132 of two ranks 110 and a second subset 134 of two ranks 110 can simulate two memory modules each with two ranks of memory devices. In embodiments in which the memory module 100 is installed in memory slot 0, corresponding to a memory slot address of (0,0,0), the 4-rank memory module 100 simulates a first 2-rank memory module in memory slot 0 having a memory slot address of (0,0,0) and a second two-rank memory module in memory slot 2 having a memory slot address of (0,1,0). The first SPD device 106 responds to queries from the BIOS by supplying data characterizing the first subset 132 of ranks 110 as being on a memory module in memory slot 0. The second SPD device 108 responds to queries from the BIOS by supplying data characterizing the second subset 134 of ranks 110 as being on a memory module in memory slot 2. The memory controller accesses the first subset 132 of ranks 110 with chip-select signals CS#0 and CS#1 (which the computer system and BIOS associate with memory slot 0), and the second subset 134 of ranks 110 with chip-select signals CS#4 and CS#5 (which the computer system and BIOS associate with memory slot 2). In a similar way, a two-rank memory module 100 with two SPD devices 106, 108 can simulate two memory modules each with one rank of memory devices.

In an alternative embodiment schematically illustrated by FIG. 3B, the second address inputs 206, 216 of the first and second SPD devices 106, 108 are electrically coupled together, the third address inputs 208, 218 of the first and second SPD devices 106, 108 are electrically coupled together, and the first address input 214 of the second SPD device 108 is electrically coupled to the first address input 204 of the first SPD device 106 via an inverter 230. An input of the inverter 230 is electrically coupled to the first address bit 204 of the first SPD device 106 and an output of the inverter 230 is electrically coupled to the first address bit 214 of the second SPD device 108.

As described above in relation to FIG. 3A, the first SPD device 106 and the second SPD device 108 of FIG. 3B have different polling addresses regardless of the memory slot address signals received by the memory module 100 from the memory controller. Table 3 shows the first polling address of the first SPD device 106 and the second polling address of the second SPD device 108 for various memory slots in which the memory module 100 schematically illustrated by FIG. 3B can be installed.

TABLE 3

| | | First polling | Second polling |
|---|---|---|---|
| Memory slot | Memory slot | address of | address of |
| occupied by the | address | first SPD device | second SPD device |
| memory module | signals | (SA2, SA1, SA0) | (SA2, SA1, SA0) |
| 0 | (0, 0, 0) | (0, 0, 0) | (0, 0, 1) |
| 1 | (0, 0, 1) | (0, 0, 1) | (0, 0, 0) |
| 2 | (0, 1, 0) | (0, 1, 0) | (0, 1, 1) |
| 3 | (0, 1, 1) | (0, 1, 1) | (0, 1, 0) |
| 4 | (1, 0, 0) | (1, 0, 0) | (1, 0, 1) |
| 5 | (1, 0, 1) | (1, 0, 1) | (1, 0, 0) |
| 6 | (1, 1, 0) | (1, 1, 0) | (1, 1, 1) |
| 7 | (1, 1, 1) | (1, 1, 1) | (1, 1, 0) |

As described above in relation to the embodiment of FIG. 3A, certain embodiments of the memory module 100 of FIG. 3B simulate two virtual or “pseudo” memory modules with two different addresses and comprising respective subsets of the ranks 110 of the memory module 100. For example, a 4-rank memory module 100 comprising a first subset 132 of two ranks 110 and a second subset 134 of two ranks 110 can simulate two memory modules each with two ranks of memory devices. In embodiments in which the memory module 100 of FIG. 3B is installed in memory slot 0 (corresponding to a memory slot address of (0,0,0)), the 4-rank memory module 100 simulates a first 2-rank memory module in memory slot 0 and a second 2-rank memory module in memory slot 1. The memory controller accesses the first subset 132 of ranks 110 with chip-select signals CS#0 and CS#1 (which the computer system and BIOS associate with memory slot 0), and accesses the second subset 134 of ranks 110 with chip-select signals CS#2 and CS#3 (which the computer system and BIOS associate with memory slot 1). In a similar way, a two-rank memory module 100 with two SPD devices 106, 108 can simulate two memory modules each with one rank of memory devices.

FIG. 3C schematically illustrates an alternative embodiment of the memory module 100 with two SPD devices 106, 108. The first set 202 of address inputs of the first SPD device 106 are configured to receive address signals from the memory controller through the memory slot 220 and the connector 136. The first address input 204 of the first SPD device 106 and the first address input 214 of the second SPD device 108 are electrically coupled together; and the third address input 208 of the first SPD device 106 and the third address input 218 of the second SPD device 108 are electrically coupled together. The second address bit 206 of the first SPD device 106 is electrically coupled to the connector 136 of the memory module 100 to receive the second bit of the memory slot address signal. The second address bit 216 of the second SPD device 108 is electrically coupled to a logic-high voltage signal (V_{H}). In other embodiments, a logic-low voltage signal (e.g., ground) is used instead of the logic-high voltage signal V_{H}.

In the embodiment schematically illustrated by FIG. 3C, the first SPD device 106 and the second SPD device 108 can have different polling addresses depending on the memory slot address signals received by the memory module 100 from the memory controller. Table 4 shows the first polling address of the first SPD device 106 and the second polling address of the second SPD device 108 for various memory slots in which the memory module 100 schematically illustrated by FIG. 3C can be installed.

TABLE 4

| | | | Second polling |
|---|---|---|---|
| Memory slot | Memory | First polling address | address of second |
| occupied by the | slot address | of first SPD device | SPD device |
| memory module | signals | (SA2, SA1, SA0) | (SA2, SA1, SA0) |
| 0 | (0, 0, 0) | (0, 0, 0) | (0, 1, 0) |
| 1 | (0, 0, 1) | (0, 0, 1) | (0, 1, 1) |
| 2 | (0, 1, 0) | (0, 1, 0) | (0, 1, 0) |
| 3 | (0, 1, 1) | (0, 1, 1) | (0, 1, 1) |
| 4 | (1, 0, 0) | (1, 0, 0) | (1, 1, 0) |
| 5 | (1, 0, 1) | (1, 0, 1) | (1, 1, 1) |
| 6 | (1, 1, 0) | (1, 1, 0) | (1, 1, 0) |
| 7 | (1, 1, 1) | (1, 1, 1) | (1, 1, 1) |

In certain embodiments in which the memory module 100 receives a memory slot address having a second bit equal to zero (e.g., (0,0,0), (0,0,1), (1,0,0), or (1,0,1)), the first polling address of the first SPD device 106 is different from the second polling address of the second SPD device 108. In certain such embodiments, the memory module 100 simulates two virtual or “pseudo” memory modules in two separate memory slots with two different addresses comprising respective subsets of the ranks 110 of the memory module 100. Such embodiments do not provide the same level of flexibility as the embodiments of FIGS. 3A and 3B with regard to installation of the memory module 100 in selected memory slots, since the memory module 100 can not be installed in a memory slot without a second address bit equal to zero. However, such embodiments can be inexpensive to implement.

For example, a 4-rank memory module 100 as schematically illustrated in FIG. 3C with a first subset 132 of two ranks 110 and a second subset 134 of two ranks 110 can simulate two memory modules each with two ranks of memory devices. In embodiments in which the memory module 100 of FIG. 3C is installed in memory slot 0 (corresponding to a memory slot address of (0,0,0)), the 4-rank memory module 100 simulates a first 2-rank memory module in memory slot 0 and a second 2-rank memory module in memory slot 2. The memory controller accesses the first subset 132 of ranks 110 with chip-select signals CS#0 and CS#1, and the second subset 134 of ranks 110 with chip-select signals CS#4 and CS#5. In a similar way, a two-rank memory module 100 with two SPD devices 106, 108 can simulate two memory modules each with one rank of memory devices.

In an alternative embodiment schematically illustrated by FIG. 3D, the second address inputs 206, 216 of the first and second SPD devices 106, 108 are electrically coupled together, and the third address inputs 208, 218 of the first and second SPD devices 106, 108 are electrically coupled together. The first address bit 204 of the first SPD device 106 is electrically coupled to the connector 136 of the memory module 100 to receive the first bit of the memory slot address signal. The first address bit 214 of the second SPD device 108 is electrically coupled to a logic-high voltage signal (V_{H}). In other embodiments, a logic-low voltage signal (e.g., ground) is used instead of the logic-high voltage signal V_{H}.

As described above in relation to FIG. 3C, the first SPD device 106 and the second SPD device 108 can have different polling addresses depending on the memory slot address signals received by the memory module 100 from the memory controller. Table 5 shows the first polling address of the first SPD device 106 and the second polling address of the second SPD device 108 for various memory slots in which the memory module 100 schematically illustrated by FIG. 3D can be installed.

TABLE 5

| | | First polling | Second polling |
|---|---|---|---|
| Memory slot | Memory slot | address of | address of |
| occupied by the | address | first SPD device | second SPD device |
| memory module | signals | (SA2, SA1, SA0) | (SA2, SA1, SA0) |
| 0 | (0, 0, 0) | (0, 0, 0) | (0, 0, 1) |
| 1 | (0, 0, 1) | (0, 0, 1) | (0, 0, 1) |
| 2 | (0, 1, 0) | (0, 1, 0) | (0, 1, 1) |
| 3 | (0, 1, 1) | (0, 1, 1) | (0, 1, 1) |
| 4 | (1, 0, 0) | (1, 0, 0) | (1, 0, 1) |
| 5 | (1, 0, 1) | (1, 0, 1) | (1, 0, 1) |
| 6 | (1, 1, 0) | (1, 1, 0) | (1, 1, 1) |
| 7 | (1, 1, 1) | (1, 1, 1) | (1, 1, 1) |

In certain embodiments in which the memory module 100 receives a memory slot address having a first address bit equal to zero (e.g., (0,0,0), (0,1,0), (1,0,0), or (1,1,0)), the first polling address of the first SPD device 106 is different from the second polling address of the second SPD device 108. In certain such embodiments, the memory module 100 simulates two virtual or “pseudo” memory modules in two separate memory slots with two different addresses comprising respective subsets of the ranks 110 of the memory module 100. Such embodiments do not provide the same level of flexibility as the embodiments of FIGS. 3A and 3B with regard to installation of the memory module 100 in selected memory slots, since the memory module 100 can not be installed in a memory slot without a first address bit equal to zero. However, such embodiments can be inexpensive to implement.

For example, a 4-rank memory module 100 as schematically illustrated in FIG. 3D with a first subset 132 of two ranks 110 and a second subset 134 of two ranks 110 can simulate two memory modules each with two ranks of memory devices. In embodiments in which the memory module 100 of FIG. 3D is installed in memory slot 0 (corresponding to a memory slot address of (0,0,0)), the 4-rank memory module 100 simulates a first 2-rank memory module in memory slot 0 and a second 2-rank memory module in memory slot 1. The memory controller accesses the first subset 132 of ranks 110 with chip-select signals CS#0 and CS#1, and the second subset 134 of ranks 110 with chip-select signals CS#2 and CS#3. In a similar way, a two-rank memory module 100 with two SPD devices 106, 108 can simulate two memory modules each with one rank of memory devices.

FIG. 3E schematically illustrates another alternative embodiment of a memory module 100 having two SPD devices 106, 108. The first set 202 of address inputs of the first SPD device 106 are configured to receive address signals from the memory controller through the memory slot 220 and the connector 136. The first address bit 214 of the second SPD device 108 is electrically coupled to a logic-high voltage signal (V_{H}) via a first pull-up resistor 244 and is reversibly electrically coupled to the first address bit 204 of the first SPD device 106 via a first jumper 254. The second address bit 216 of the second SPD device 108 is electrically coupled to a logic-high voltage signal (V_{H}) via a second pull-up resistor 246 and is reversibly electrically coupled to the second address bit 206 of the first SPD device 106 via a second jumper 256. The third address bit 218 of the second SPD device 108 is electrically coupled to a logic-high voltage signal (V_{H}) via a third pull-up resistor 248 and is reversibly electrically coupled to the third address bit 208 of the first SPD device 106 via a third jumper 258. In certain other embodiments, rather than being electrically coupled to a logic-high voltage signal, one or more of the address bits of the second SPD device 108 is electrically coupled to a logic-low voltage signal (e.g., ground).

In certain embodiments, a selected one or two of the jumpers 254, 256, 258 are removed and a selected one or two of the jumpers 254, 256, 258 remain, thereby tailoring the polling address of the second SPD device 108. By allowing a jumper to remain, the corresponding address bits of the first SPD device 106 and the second SPD device 108 are electrically coupled together such that both address bits are provided by the corresponding address bit of the memory slot address. By removing a jumper, the corresponding address bits of the first SPD device 106 and the second SPD device 108 are no longer electrically coupled together such that the address bit of the second SPD device 108 is held high by virtue of the electrical connection to V_{H} via the corresponding pull-up resistor. In certain embodiments, the resistance of each of the pull-up resistors 244, 246, 248 is selected to have a minimal effect on the address bits of the second SPD device 108 from V_{H} if the corresponding jumper remains in place. Typical values of the resistance of each pull-up resistor 244, 246, 248 includes, but is not limited to, 100,000 ohms. In certain embodiments, each of the jumpers 254, 256, 258 has a resistance of approximately zero ohms.

For example, in one embodiment, the first jumper 254 is removed and the second and third jumpers 256, 258 remain in place. By removing the first jumper 254, the first address bit 214 of the second SPD device 108 is no longer equal to the first address bit 204 of the first SPD device 106. Instead, the first address bit 214 of the second SPD device 108 is held high by virtue of the electrical connection to V_{H} via the pull-up resistor 244. In addition, by allowing the second jumper 256 and the third jumper 258 to remain, the second address bits 206, 216 of the first and second SPD devices 106, 108 are equal to one another and the third address bits 208, 218 of the first and second SPD devices 106, 108 are equal to one another. Such a configuration is equivalent to the embodiment schematically illustrated by FIG. 3D, and the polling addresses of the first SPD device 106 and the second SPD device 108 for installation of the memory module 100 in various memory slots are then given by Table 5. In other embodiments, the second jumper 256 is removed while the first and third jumpers 254, 258 remain in place, resulting in a configuration equivalent to the embodiment schematically illustrated by FIG. 3C and Table 4. Other combinations of one removed jumper and two remaining jumpers, or two removed jumpers and one remaining jumper are compatible with embodiments described herein.

Embodiments such as schematically illustrated by FIG. 3E are capable of being modified to be compatible with various configurations. However, such embodiments do not provide the same level of flexibility as the embodiments of FIGS. 3A and 3B with regard to installation of the memory module 100 in selected memory slots, as described above in relation to the embodiments of FIGS. 3C and 3D. However, such embodiments can be inexpensive to implement.

In certain embodiments, a memory module 100 comprises more than four ranks 110 on the PCB 122. In certain such embodiments, the memory module 100 comprises an SPD device for each pair of ranks 110 of memory devices 104 on the memory module 100.

Computer System Utilizing at Least One 4-Rank Memory Module

In certain embodiments, the computer system utilizes at least one memory module 100 having four ranks 110 of memory devices 104. Because the 4-rank memory module 100 advantageously offers twice as much memory density per memory module as a 2-rank JEDEC-standard memory module, certain such embodiments provide increased memory capacity above that provided by computer systems utilizing only standard two-rank memory modules. Certain other embodiments in which the memory slots are on a motherboard of the computer system advantageously reduce the motherboard footprint by decreasing the number of memory slots used to accommodate the desired memory capacity.

In addition, in certain embodiments, the 4-rank memory module 100 is utilized to improve the capacitive loading of the computer system. Capacitive loading of a computer system limits the number of memory slots a computer system can support at higher bandwidths, thereby creating a tradeoff between bandwidth and memory density. The distribution of loads on stub buses and the combination of loads in each memory slot can cause signal reflections which restrict operation frequency. Total stub capacitances associated with the use of additional memory slots reduces the bus speed (and bandwidth) thereby limiting the memory density available to the computer system. As a result, to achieve higher bandwidths, the number of memory slots used by the computer system is correspondingly reduced.

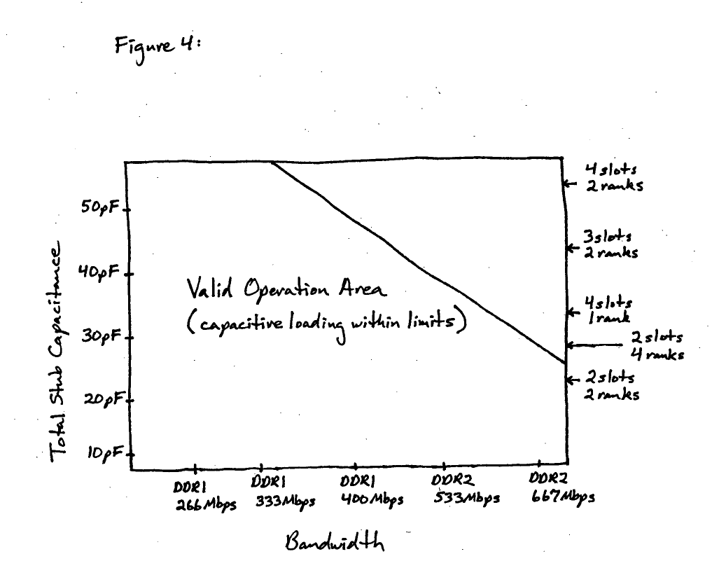

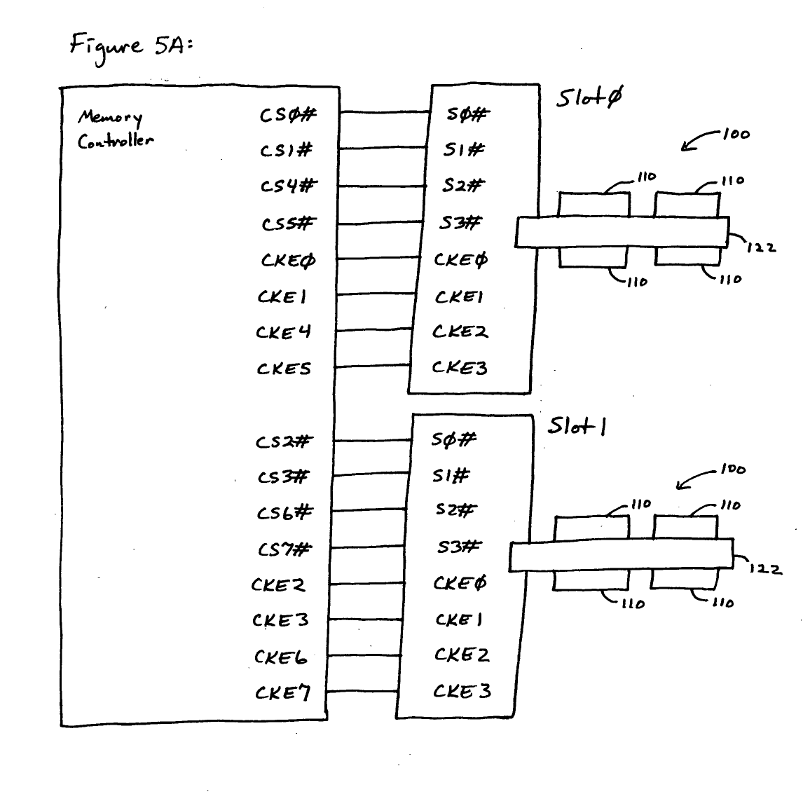

FIG. 4 schematically illustrates the tradeoff between the bandwidth and memory density for various types of DDR memory modules. For higher bandwidths, the valid operation area to maintain a maximum total stub capacitance is reduced. Thus, fewer ranks and memory slots are supported and the memory density is correspondingly reduced within the valid operation area. Memory slots contribute to the stub loading as well, such that two slots with 4 ranks per slot presents a smaller load to the computer system than does four slots with 2 ranks per slot. Another factor is signal resonance between memory slots, which is a combinatorial effect that increases the effective loading on the memory controller by causing signal perturbations that delay or slow signals.

A configuration of 4 memory slots with 2 ranks per slot (i.e., a 4×2 configuration) has eight loads per data line, which is the same number of loads per data line of a configuration of 2 memory slots with 4 ranks per slot (i.e., a 2×4 configuration). However, the signal loading per data line for the 2×4 configuration is actually less than that of the 4×2 configuration when the combinatorial effects of memory slot loading are considered. There are 144 combinations to be verified for a computer system with 4 memory slots in which any memory slot can hold a memory module with 0, 1, or 2 ranks. In contrast, a computer system with 2 memory slots that supports 0, 1, 2, or 4 ranks per memory slot has 64 combinations, a 45% reduction in complexity. In addition, the electrical loading of a 4-rank memory module 100 can be more carefully controlled, thereby making the closure of timing budgets easier. By avoiding using additional memory slots, in certain embodiments, the 4-rank memory module 100 advantageously avoids increases in loading effects which would degrade performance in high-speed or high-bandwidth systems, thereby providing a cost-effective solution that meets the density requirements of high performance computing while maintaining the desired performance specifications.

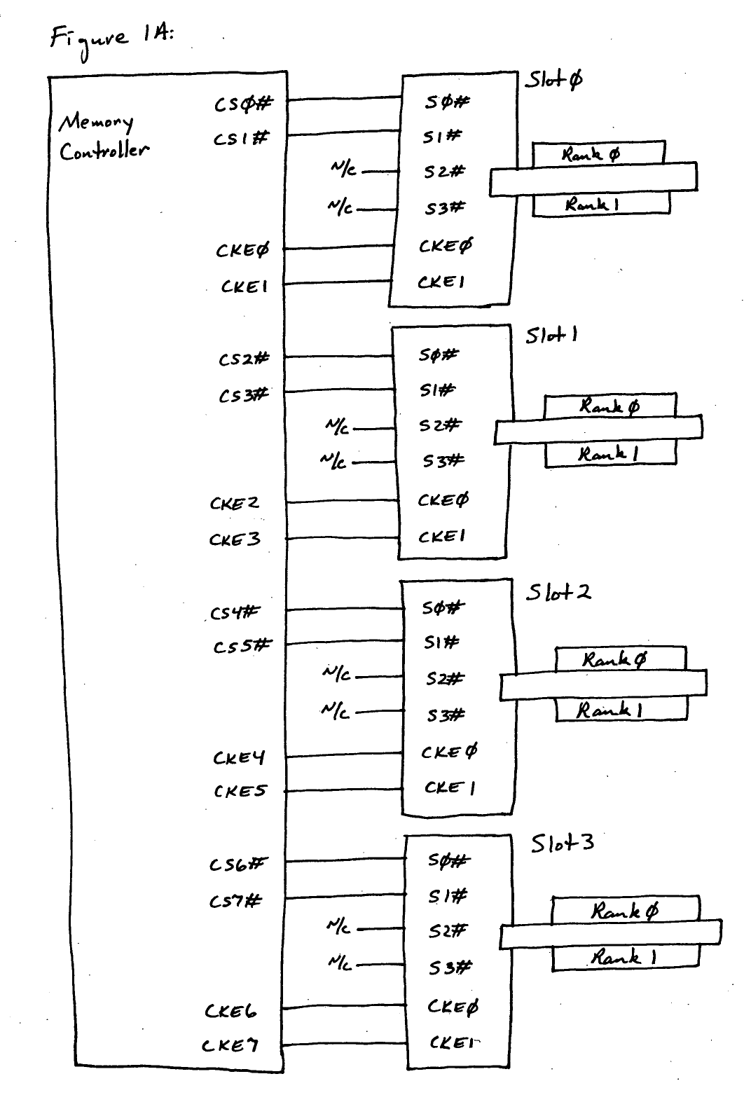

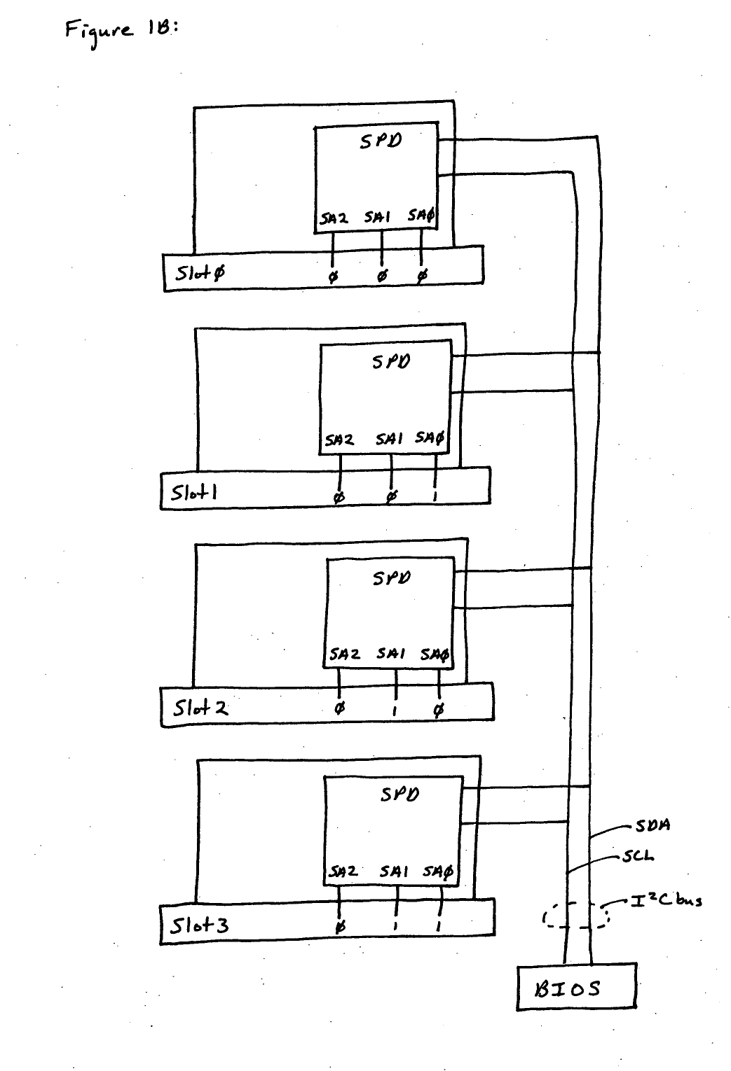

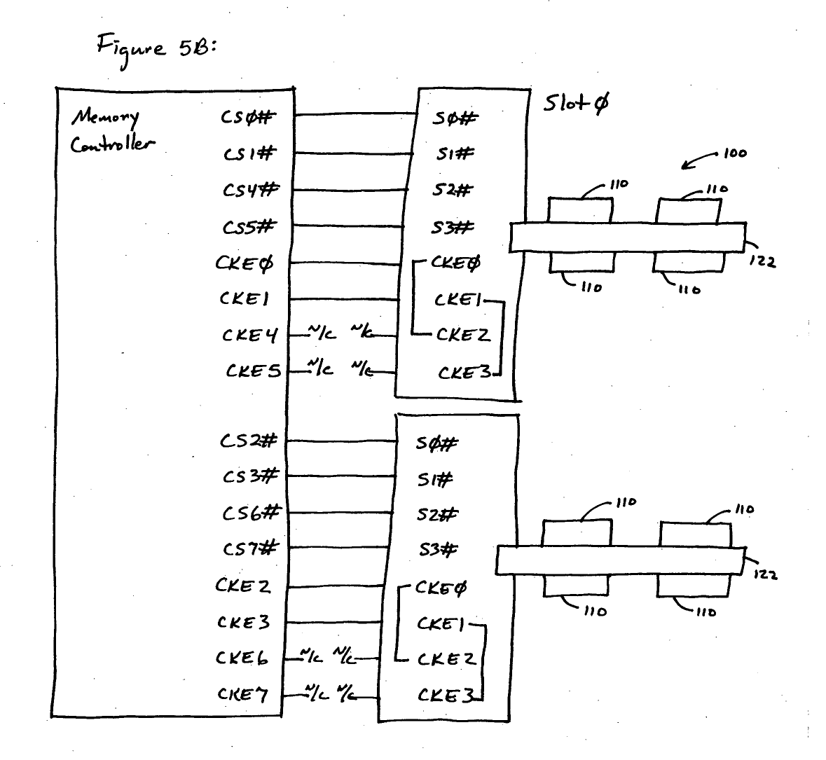

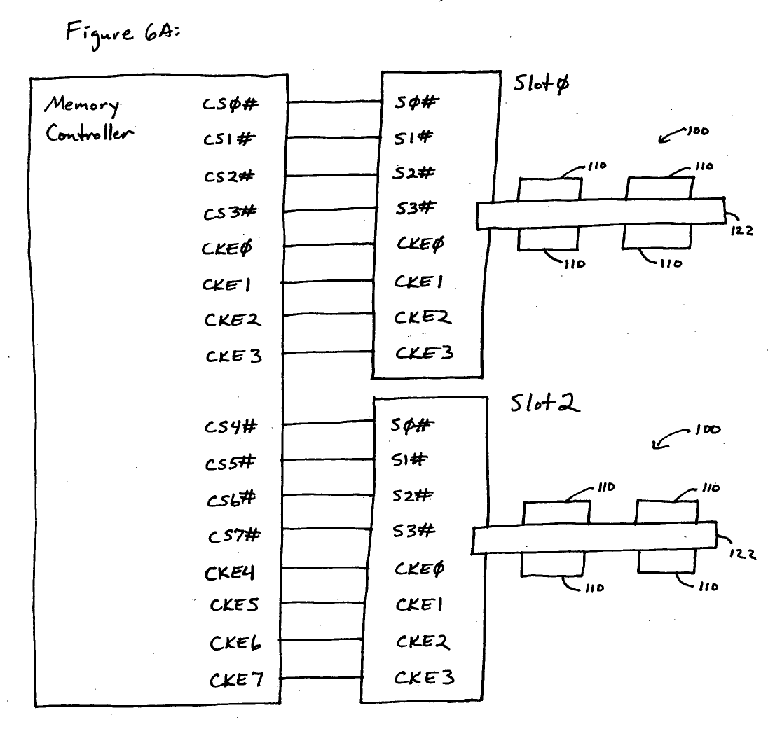

Various embodiments support 4-rank memory modules 100 utilizing different configurations of memory slots. In certain embodiments, schematically illustrated by FIGS. 5A and 5B, the chip-select signals that would have been routed to memory slots 2 and 3 in the standard configuration schematically illustrated by FIG. 1A are instead routed to the rank-select inputs of memory slots 0 and 1 which are unused on standard 2-rank memory modules (i.e., S2# and S3#). In addition, the CKE signals that would have been routed to memory slots 2 and 3 in the standard configuration of FIG. 1A are instead routed to the corresponding CKE inputs of the 4-rank memory modules 100 of memory slots 0 and 1.

The embodiments schematically illustrated by FIGS. 5A and 5B reduce the number of memory slots being used from 4 memory slots per memory channel to two memory slots per memory channel without reducing total memory capacity. In certain such embodiments, the standard BIOS code polls what electrically appear to be four separate memory slots and configures the memory controller to enable the appropriate chip-select signals. In certain such embodiments, both SPD devices 106, 108 are programmed as though each is associated with a two-rank memory module (i.e., SPD Byte 5=2), and responds to a unique SA address. To the BIOS, the 4-rank memory module 100 appears as two separate 2-rank memory modules. The other portions of the SPD programming describe the two ranks as being the total module capacity.

Such embodiments also retain a similarity with the standard configuration of 4 memory slots in that memory slot 0 remains associated with chip-select signals CS0# and CS1# and clock-enable signals CKE0 and CKE1, and memory slot 1 remains associated with chip-select signals CS2# and CS3# and clock-enable signals CKE2 and CKE3. Such embodiments logically associate the chip-select signals and the clock-enable signals to the correct memory slot as shown in Table 6, thereby maintaining the correlation between the chip-select signals and the SPD addresses which are used with standard two-rank memory modules.

TABLE 6

| | 4 Slots, Standard 2 | | | 2 Slots, Non-standard | | |
|---|---|---|---|---|---|---|
| | Ranks per Slot | | | 4 Ranks per Slot | | |
| | (e.g., FIG. 1A) | | | (e.g., FIG. 5A) | | |
| | | | Clock- | | Chip- | Clock- |
| SPD | | Chip-Select | Enable | | Select | Enable |
| Address | Slot | Signals | Signals | Slot | Signals | Signals |
| (0, 0, 0) | 0 | CS0#/CS1# | CKE0/CKE1 | 0 | CS0#/ | CKE0/ |
| | | | | | CS1# | CKE1 |
| (0, 0, 1) | 1 | CS2#/CS3# | CKE2/CKE3 | 1 | CS2#/ | CKE2/ |
| | | | | | CS3# | CKE3 |
| (0, 1, 0) | 2 | CS4#/CS5# | CKE4/CKE5 | 0 | CS4#/ | CKE4/ |
| | | | | | CS5# | CKE5 |
| (0, 1, 1) | 3 | C56#/CS7# | CKE6/CKE7 | 1 | CS6#/ | CKE6/ |
| | | | | | CS7# | CKE7 |

In addition, such embodiments do not require BIOS modifications since such embodiments can alternatively be populated with standard 2-rank memory modules without having a hole or gap in the memory map that the BIOS must accommodate when initializing the computer system. Exemplary configurations of the two SPD devices 106, 108 compatible with such embodiments include, but are not limited to, the embodiments of FIG. 3A and Table 2 and of FIG. 3C and Table 4.

The embodiment schematically illustrated by FIG. 5A balances the loading on the CKE signals to that of the chip-select signals by using the two CKE inputs which are unused by the standard 2-rank memory module to wire the additional clock-enable signals of the 4-rank memory module 100. In certain embodiments, such as schematically illustrated by FIG. 5B, CKE timing is less critical. In such embodiments, CKE0 is wired to CKE2, and CKE1 is wired to CKE3 on the 4-rank memory module 100. Such embodiments double the loading on the CKE0 and CKE1 signals while eliminating the need to wire additional signals to each memory slot.

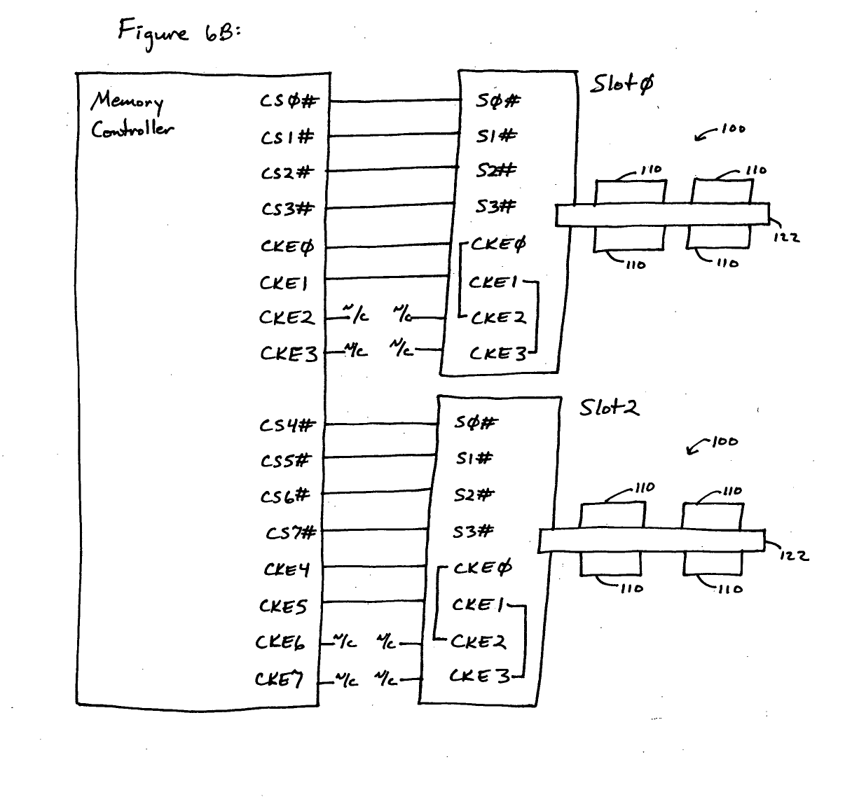

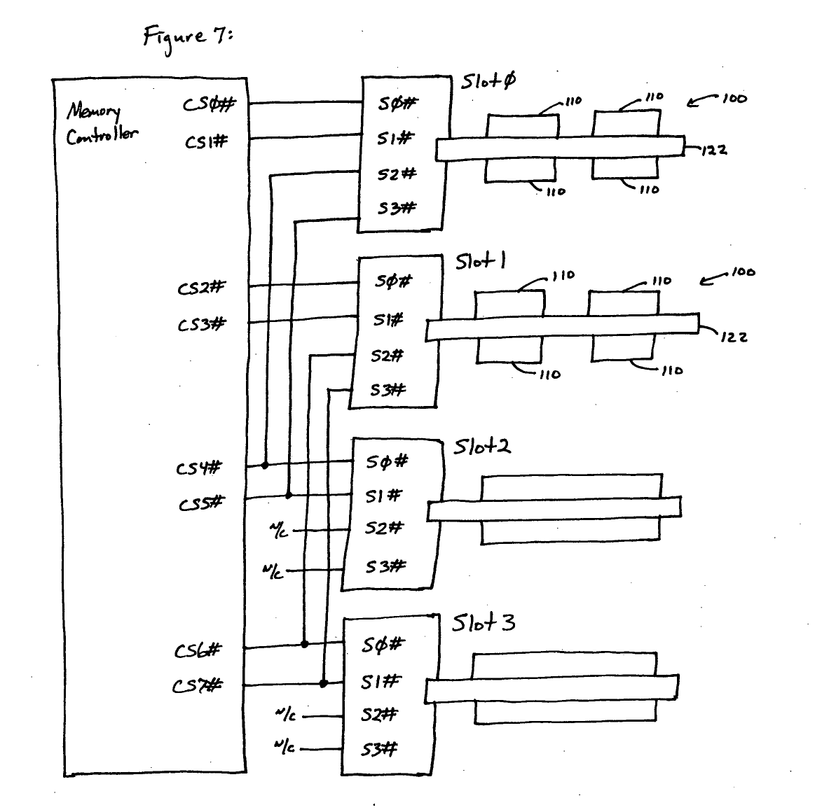

In an alternative embodiment, schematically illustrated by FIG. 6A, the chip-select signals that would have been routed to memory slot 1 in the standard configuration are instead routed to the rank-select inputs of memory slot 0, which are unused on standard 2-rank memory modules; and the chip-select signals that would have been routed to memory slot 3 in the standard configuration are instead routed to the rank-select inputs of memory slot 2, which are unused on standard 2-rank memory modules. Similarly, the CKE signals that would have been routed to memory slot 1 and memory slot 3 in the standard configuration are instead routed to the corresponding CKE inputs of the 4-rank memory modules 100 of memory slot 0 and memory slot 2, respectively. FIG. 6B schematically illustrates an embodiment in which CKE0 and CKE2 are wired together and CKE1 and CKE3 are wired together, thereby doubling the loading on the CKE0 and CKE1 signals while eliminating the need to wire additional signals to each memory slot. Exemplary configurations of the two SPD devices 106, 108 compatible with such embodiments include, but are not limited to, the embodiments of FIG. 3B and Table 3 and of FIG. 3D and Table 5.

In certain embodiments, the computer system utilizes a hybrid configuration in which standard 2-rank memory modules and non-standard 4-rank memory modules are both used. FIG. 7 schematically illustrates an exemplary computer system with two 2-rank memory modules and two 4-rank memory modules. The configuration of FIG. 7 combines the 4×2 and 2×4 approaches by sharing four chip-select signals (e.g., CS4#, CS5#, CS6#, and CS7#). However, such configurations are constrained in that improper combinations can occur in which more than one memory slot has an active memory module responding to a given chip-select signal. Such configurations advantageously provide a simple method to migrate users from two ranks per memory slot to four ranks per memory slot.

While certain embodiments have been described, these embodiments have been presented by way of example only, and are not intended to limit the scope of the invention. Indeed, the novel methods and systems described herein may be embodied in a variety of other forms. Furthermore, various omissions, substitutions and changes in the form of the methods and systems described herein may be made without departing from the spirit of the invention. The accompanying claims and their equivalents are intended to cover such forms or modifications as would fall within the scope and spirit of the invention.

1. A memory module comprising:
a printed circuit board;
a plurality of memory devices arranged in a plurality of ranks on the printed circuit board, the plurality of ranks comprising a first subset having at least one rank and a second subset having at least one rank;
a first serial-presence-detect (SPD) device on the printed circuit board, the first SPD device comprising data that characterizes the first subset; and
a second SPD device on the printed circuit board, the second SPD device comprising data that characterizes the second subset.

2. The memory module of claim 1, wherein each rank of the plurality of ranks comprises a plurality of memory devices that share a chip-select signal.

3. The memory module of claim 1, wherein the plurality of ranks comprises four ranks.

4. The memory module of claim 1, wherein the first subset comprises two ranks and the second subset comprises two ranks.

5. The memory module of claim 1, wherein the memory module is configured to provide a first address to the first SPD device and a second address to the second SPD device, wherein the first address is different from the second address.

6. The memory module of claim 5, wherein the first SPD device comprises a first set of address inputs for providing the first address.

7. The memory module of claim 6, wherein the second SPD device comprises a second set of address inputs for providing the second address, the second set of address inputs electrically coupled to the first set of address inputs.

8. The memory module of claim 7, wherein the first set of address inputs and the second set of address inputs each comprises a first address bit, a second address bit, and a third address bit.

9. The memory module of claim 8, wherein the first address bit of the first set of address inputs is electrically coupled to the first address bit of the second set of address inputs.

10. The memory module of claim 9, further comprising an inverter which electrically couples the first address bit of the first SPD device to the first address bit of the second SPD device.

11. The memory module of claim 9, further comprising a jumper which electrically couples the first address bit of the first SPD device to the first address bit of the second SPD device.

12. The memory module of claim 8, wherein the second address bit of the first SPD device is electrically coupled to the second address bit of the second SPD device.

13. The memory module of claim 12, further comprising an inverter which electrically couples the second address bit of the first SPD device to the second address bit of the second SPD device.

14. The memory module of claim 12, further comprising a jumper which electrically couples the second address bit of the first SPD device to the second address bit of the second SPD device.

15. The memory module of claim 8, wherein the third address bit of the first SPD device is electrically coupled to the third address bit of the second SPD device.

16. The memory module of claim 15, further comprising an inverter which electrically couples the third address bit of the first SPD device to the third address bit of the second SPD device.

17. The memory module of claim 15, further comprising a jumper which electrically couples the third address bit of the first SPD device to the third address bit of the second SPD device.

18. The memory module of claim 8, wherein at least one address bit of the second SPD device is electrically coupled to a logic-high signal.

19. The memory module of claim 8, wherein at least one address bit of the second SPD device is electrically coupled to a logic-low signal.

20. The memory module of claim 1, wherein the memory module is an in-line memory module.

21. The memory module of claim 1, wherein the memory module is a dual in-line memory module.

22. The memory module of claim 1, wherein the memory module is a double-data-rate dual in-line memory module.

23. The memory module of claim 1, wherein at least one of the first SPD device and the second SPD device comprises an electrically-erasable-programmable-read-only memory (EEPROM) device.

24. A computer comprising the memory module of claim 1.

25. A memory module comprising:
a first rank of memory devices;
a second rank of memory devices;
a third rank of memory devices;
a fourth rank of memory devices;
a first serial-presence-detect (SPD) device comprising data that characterizes the first rank of memory devices and the second rank of memory devices;
a second SPD device comprising data that characterizes the third rank of memory devices and the fourth rank of memory devices;
a plurality of address inputs configured to provide the first SPD device with a first polling address; and
a circuit electrically coupled to the plurality of address inputs and configured to provide the second SPD device with a second polling address different from the first polling address.

26. A method of addressing memory in a computer system, the method comprising:
providing a four-rank memory module comprising a printed circuit board, a first pair of memory ranks on the printed circuit board, a second pair of memory ranks on the printed circuit board, a first serial-presence-detect (SPD) device on the printed circuit board and comprising data that characterizes the first pair of memory ranks, and a second SPD device on the printed circuit board and comprising data that characterizes the second pair of memory ranks;
electrically connecting the four-rank memory module to a memory controller;
applying a first polling address to the first SPD device based on a physical location of the four-rank memory module in the computer system;
generating a second polling address different from the first polling address; and
applying the second polling address to the second SPD device.

27. The method of claim 26, further comprising:
providing the data that characterizes the first pair of memory ranks to the memory controller by addressing the first SPD device with the first polling address; and
providing the data that characterizes the second pair of memory ranks to the memory controller by addressing the second SPD device with the second polling address.

28. A computer memory subsystem comprising:
a memory controller;
a four-rank memory module comprising a first group of two memory ranks, a second group of two memory ranks, a first serial-presence-detect device comprising data associated with the first group of two memory ranks, and a second serial-presence-detect device comprising data associated with the second group of two memory ranks;
means for electrically connecting the four-rank memory module to the memory controller;
means for configuring the first serial-presence-detect device with a first address;
means for generating a second address for the second serial-presence-detect device from the first address; and
means for configuring the second serial-presence-detect device with the second address, wherein the first and second addresses are different.

29. A computer comprising:
a four-rank memory module that includes a first set of two memory ranks and a second set of two memory ranks;
at least one memory slot electrically coupled to the four-rank memory module; and
a memory controller electrically coupled to the memory slot to access the four-rank memory module as two independent two-rank memory modules.

30. The computer of claim 29, wherein the four-rank memory module further comprises:
a first serial-presence-detect (SPD) device comprising data that characterizes the first set of two memory ranks, the first SPD device having a first serial address; and
a second SPD device comprising data that characterizes the second set of two memory ranks, the second SPD device having a second serial address, wherein the first serial address is different from the second serial address.

31. The computer of claim 30, wherein the first SPD device comprises a first set of serial address inputs electrically coupled to the memory slot to provide the first SPD device with the first serial address.

32. The computer of claim 31, wherein the second SPD device comprises a second set of serial address inputs electrically coupled to the first set of serial address inputs, the four-rank memory module further comprising a circuit which electrically couples the first set of serial address inputs to the second set of serial address inputs to generate the second serial address from the first serial address.

33. The computer of claim 32, wherein the circuit comprises logic.

34. The computer of claim 32, wherein the circuit comprises at least one jumper.

35. A computer system comprising:
a memory controller;
a printed circuit board; and
a plurality of memory devices arranged in a plurality of ranks on the printed circuit board and electrically coupled to the memory controller, the plurality of ranks comprising a first subset having at least one rank and a second subset having at least one rank, the memory controller accessing the first subset as a first virtual memory module and accessing the second subset as a second virtual memory module.
